(19) United States
(12) Patent Application Publication
(10) Pub. No.: US 2003/0027059 A1
(43) Pub. Date: Feb. 6, 2003

(54) Method for producing a mask and method for fabricating a semiconductor device

(76) Inventor: Giorgio Schweeger, Dresden (DE)

Correspondence Address: LERNER AND GREENBERG, P.A., PATENT ATTORNEYS AND ATTORNEYS AT LAW, Post Office Box 2480, Hollywood, FL, 33022-2480, US

(21) Appl. No.: 10/210,732

(22) Filed: Jul. 31, 2002

(30) Foreign Application Priority Data
Jul. 31, 2001 (DE) 101 37 575.1

(51) Int. Cl. C03C 25/68; C03C 15/00; B44C 1/22; C23F 1/00; G03F 9/00; G03C 5/00

(52) U.S. Cl. 430/5; 430/322; 430/323; 430/324; 216/83

(57) ABSTRACT

A method for fabricating a mask includes, inter alia, producing first spacers in between masking structures that have been produced beforehand. The masking structures are subsequently removed, while the first spacers remain. The remaining first spacers thus serve as a hard mask during the patterning of underlying layers during the fabrication of a semiconductor device. One advantage of this method is the reduction of feature sizes that can be fabricated. In one embodiment variant of the method, after the removal of the masking structures, second spacers are produced between the first spacers. This allows for the fabrication of the smallest possible periodic structures.

### BACKGROUND OF THE INVENTION

Field of the Invention

Cost reductions of up to 30% are required annually in the semiconductor business in order to still obtain a profit as prices continually fall. The required cost reduction is traditionally effected by reducing the size of the semiconductor structures, particularly in the memory area. In this case, the feature sizes are already smaller than half the wavelength of the best lithography apparatuses on the market. Rising costs for lithography apparatuses and an increasing delay in their availability nowadays impose a limit on the further miniaturization of structures.

On the other hand, it is problematic to produce smaller structures without being limited by lithographic specifications. At the present time, the industry does not have a customary non-optical method for solving the problem described above.

As is known, attempts are being made to improve the resolution with the available wavelengths by using optical methods (alternating phase shift masks). Equally, holographic methods for producing fine gratings have been tested. However, these have failed due to the fact that they have not made it possible to simultaneously fabricate structures with different periodicity, and due to problems of alignability with respect to other structures that have been fabricated in preceding process steps.

U.S. Pat. No. 6,008,123 describes a method for fabricating an opening in a semiconductor layer by using spacers. However, the resolution capability is limited in the case of this method, too.

### SUMMARY OF THE INVENTION

It is accordingly an object of the invention to at least reduce the disadvantages discussed above.

With the foregoing and other objects in view there is provided, in accordance with the invention, a method for producing a mask for fabricating a semiconductor device, that includes the following steps: applying a masking layer to a substrate; selectively removing regions of the masking layer for forming masking structures; applying a first layer to the masking structures and also in interspaces between the masking structures; selectively removing regions of the first layer for forming first spacers between the masking structures; and removing the masking structures for forming the mask from the first spacers for subsequently producing structures of the semiconductor device.

In accordance with an added feature of the invention, the mask forms a hard mask.

In accordance with an additional feature of the invention, the step of selectively removing the regions of the masking layer is carried out by performing a selective etching.

In accordance with another feature of the invention, the selective etching is a dry etching.

In accordance with a further feature of the invention, the step of selectively removing the regions of the first layer is carried out by performing a selective etching.

In accordance with a further added feature of the invention, the selective etching of the first layer is an anisotropic etching.

In accordance with a further aditional feature of the invention, the step of applying the first layer to the masking structures is carried out by performing an isotropic deposition.

In accordance with yet an added feature of the invention, the step of removing the masking structures is carried out by performing a selective wet etching.

In accordance with yet an additional feature of the invention, the first layer is made of oxide.

In accordance with yet another feature of the invention, the first layer is made of nitride.

In accordance with yet a further feature of the invention, the masking layer includes a first masking layer and a second masking layer applied to the first masking layer.

In accordance with an added feature of the invention, the second masking layer is more resistant to a dry etching than the first masking layer.

In accordance with an additional feature of the invention, the second masking layer can be etched selectively with respect to the first masking layer.

In accordance with another feature of the invention, the second masking layer is made of polysilicon.

In accordance with a further feature of the invention, the first masking layer is made of oxide.

In accordance with a further added feature of the invention, the first masking layer is made of nitride.

In accordance with a further additional feature of the invention, each one of the masking structures has a width equal to about a third of a distance between two of the masking structures.

In accordance with yet an added feature of the invention, each one of the first spacers has a width that is essentially equal to a distance between two of the first spacers.

In accordance with yet an additional feature of the invention, each one of the masking structures has a width that is essentially equal to the width of each one of the first spacers.

In accordance with yet another feature of the invention, the method includes steps of: applying a second layer to the first spacers and also into interspaces lying between the first spacers; and selectively removing regions of the second layer for forming second spacers between the first spacers.

In accordance with yet a further feature of the invention, the step of selectively removing the regions of the second layer is carried out by performing a selective etching.

In accordance with an added feature of the invention, the selective etching that is performed to selectively remove the regions of the second layer is an anisotropic etching.

In accordance with an additional feature of the invention, the step of applying the second layer is carried out by performing an isotropic deposition.

In accordance with another feature of the invention, the second layer is made of oxide.

In accordance with a further feature of the invention, the second layer is made of nitride.

In accordance with a further added feature of the invention, each one of the first spacers has a width equaling approximately one third of a width of each one of the masking structures.

In accordance with a further additional feature of the invention, L+D=S−D, where L is a width of each one of the masking structures, S is a distance between two of the masking structures, and D is a width of each one of the first spacers.

In accordance with yet an added feature of the invention, the width of each one of the first spacers is approximately equal to a width of each one of the second spacers.

With the foregoing and other objects in view there is also provided, in accordance with the invention, a method for fabricating a semiconductor device, which includes steps of: providing a substrate; applying a layer, which will be patterned, to the substrate; applying a mask to the layer that will be patterned by: applying a masking layer to the substrate, selectively removing regions of the masking layer for forming masking structures, applying a first layer to the masking structures and also in interspaces between the masking structures, selectively removing regions of the first layer for forming first spacers between the masking structures, and removing the masking structures for forming the mask from the first spacers for subsequently producing structures of the semiconductor device. The mask is used to pattern the layer.

In accordance with an added feature of the invention, the method includes steps of: applying a second layer to the first spacers and also into interspaces lying between the first spacers; selectively removing regions of the second layer for forming second spacers between the first spacers; applying a protective layer above at least one of the masking structures after forming the first spacers; removing ones of the masking structures that are not provided with the protective layer; and removing the protective layer.

In accordance with an additional feature of the invention, the protective layer is formed by a photoresist mask.

In other words, the invention provides a method for producing a mask for fabricating a semiconductor device, having the following steps: applying a masking layer to a substrate; selectively removing regions of the masking layer for forming masking structures; applying a first layer to the masking structures and also in interspaces between the masking structures; selectively removing regions of the first layer for forming first spacers between the masking structures; and removing the masking structures for forming a mask from the first spacers for subsequently producing structures of the semiconductor device.

Thus, a mask including spacers is fabricated. In this case, the mask thus fabricated is preferably a so-called hard mask. Since the minimum dimensions of spacers that can be produced are smaller than the masking structures that are fabricated by using lithography, a higher mask resolution is achieved. A higher mask resolution in turn makes it possible to fabricate smaller semiconductor structures.

In conventional methods of mask fabrication, the minimum structure dimensions that can be fabricated correspond to the distances between the masking structures. In the case of such methods, spacers can serve for aligning these distances (also see U.S. Pat. No. 6,008,123). Since, particularly during the fabrication of periodic structures, the distances between the masking structures must be equal to the width thereof, the miniaturization of such structures that will be fabricated is nonetheless dependent on the possible miniaturization of the masking structures. This limitation is overcome by the inventive approach of using spacers as a hard mask.

In a first refinement of the invention, the width of each masking structure amounts to about a third of the distance between two masking structures. In this case, the first spacers provided thereon are approximately just as wide as the masking structures. As a result, after removing the masking structures, in an underlying layer, it is possible to fabricate a periodic structure whose period is half as large as that of the masking structures that are removed. Since the periodicity determines the wavelength of the light when fabricating the masking structures by lithography, this step is adversely affected by associated restrictions to a lesser extent than in the case when fabricating masking structures using direct lithography.

One refinement of the invention additionally has the following steps: applying a second layer to the first spacers and also into the interspaces lying between the first spacers; and selectively removing regions of the second layer for forming second spacers between the first spacers. This refinement has the advantage that the required thickness of the layer that will be applied for fabricating the spacers is reduced. This simplifies the fabrication of the spacers and reduces the aspect ratios of the masking, which additionally results in an improvement in the process tolerance. This refinement, called the double spacer method because first and second spacers are used, thus makes it possible, in a particularly advantageous manner, to fabricate regular structures having different periodicities and different structure widths, and at the same time, to fabricate periodic lithographic structures and larger non-periodic structures by using very simple lithographic methods.

In this exemplary embodiment, the width of structures that will be fabricated depends on the width of the masking structures only to a certain extent or not at all.

By way of example, the width of each first spacer approximately corresponds to one third of the width of each masking structure, and the width of each first spacer is approximately equal to the width of each second spacer. As a result, it is possible to produce periodic structures whose maximum resolution (i.e. whose minimum dimensioning) is again improved compared with the “single spacer method” (i.e. when using only the first spacers).

In an advantageous manner, a mask fabricated by the inventive method can be used in a method for fabricating a semiconductor device, having the following steps: providing a substrate; applying a layer that will be patterned to the substrate; applying the mask to the layer that will be patterned; and patterning the layer that will be patterned by using the mask.

In one embodiment variant, it is additionally possible to apply a protective layer above one or more of the masking structures after forming the first spacers, and then to remove it again after forming the second spacers. This makes it possible to simultaneously fabricate small periodic and larger individual structures.

According to the teaching of the invention, thin spacers are used as a hard mask. Regular and irregular structures can thus be fabricated simultaneously. The reduction of the structure width amounts to at least 1:2 in relation to the pure lithography process. Thin spacers can be fabricated more uniformly and make it possible to provide thin hard masks for an improved patternability of underlying layers.

Other features which are considered as characteristic for the invention are set forth in the appended claims.

Although the invention is illustrated and described herein as embodied in a Method for producing a mask and method for fabricating a semiconductor device, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a diagrammatic cross sectional view through a semiconductor device with masking structures for fabricating a mask in accordance with a first exemplary embodiment of an inventive method;

FIG. 2 is a diagrammatic cross sectional view through the semiconductor device shown in FIG. 1, in which a layer has been applied to the masking structures;

FIG. 3 is a diagrammatic cross sectional view through the semiconductor device shown in FIG. 2, after regions of the applied layer have been selectively etched away to produce spacers;

FIG. 4 is a diagrammatic cross sectional view through the semiconductor device shown in FIG. 3, after the masking structures have been selectively etched away and the layer located underneath has been patterned;

FIG. 5 is a diagrammatic cross sectional view through a semiconductor device with masking structures for fabricating a mask according to a second exemplary embodiment of the inventive method;

FIG. 6 is a diagrammatic cross sectional view through the semiconductor device shown in FIG. 5, with first spacers on the masking structures;

FIG. 7 is a diagrammatic cross sectional view through the semiconductor device shown in FIG. 6 after removing the masking structures, with additional spacers on the first spacers;

FIG. 8 is a diagrammatic cross sectional view through the semiconductor device shown in FIG. 7, after a layer located underneath has been selectively etched away;

FIG. 9 is a diagrammatic cross sectional view through a semiconductor device with a photoresist mask for fabricating a mask according to one variant of the inventive method; and

FIG. 10 is a diagrammatic cross sectional view through the semiconductor device shown in FIG. 9, with first and second spacers.

### DESCRIPTION OF THE PREFERRED EMBODIMENTS

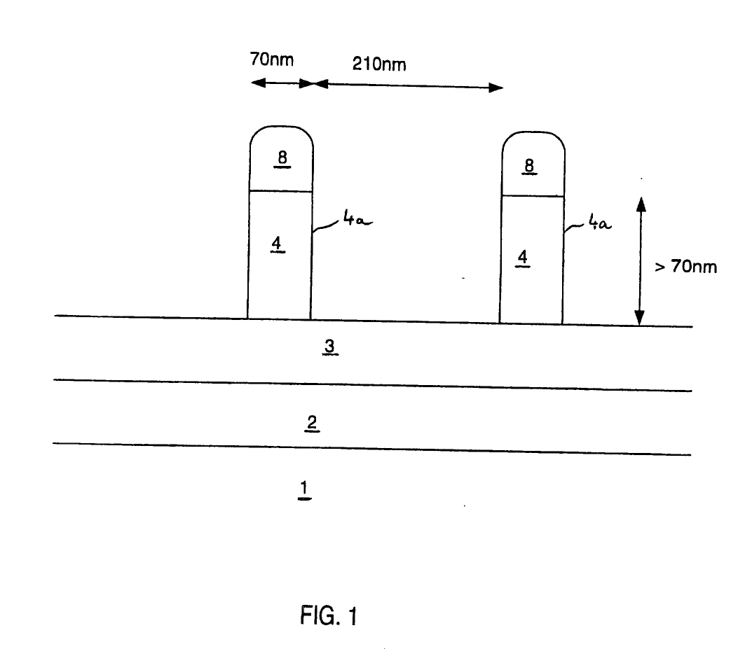

A first exemplary embodiment of a method for fabricating a mask for patterning a semiconductor device will now be explained with reference to FIGS. 1 to 4. The first exemplary embodiment of the method is also referred to as the “single spacer method” in this description. FIG. 1 diagrammatically shows a cross sectional view of a substrate 1, on which a layer 2 to be patterned and also a first masking layer 3 are applied. Typically, the substrate 1 is composed of silicon, the layer 2 to be patterned is composed of a material or a material sequence for an interconnect (e.g. polysilicon or metal), and the first masking layer 3 is composed of oxide or nitride. A second masking layer 4 is applied on the first masking layer 3, and is generally resistant to a dry etching of the first masking layer 3, but conversely, the second masking layer 4 can also be dry-etched selectively with respect to the first masking layer 3. The second masking layer 4 is typically a polysilicon layer.

Although the dimensions in the figures are merely shown as an example, it can be discerned that the second masking layer is sufficiently thick in relation to the later structure width. Such a thickness is provided in order to form the basis for a sufficient profiling for a layer that subsequently will be applied for forming “spacers”.

The second masking layer 4 is patterned selectively with respect to the first masking layer 3 by using a photoresist layer 8 and dry etching. In this case, the width of the structures 4a thus formed must already be, for instance, as small as the width of the interconnects that will be fabricated. On the other hand, the periodicity of the structures 4a is twice as large as that of the interconnects to be fabricated. Since the periodicity determines the wavelength of the light that will be used for the lithography step, it is thereby possible to halve the feature sizes compared with conventional pure lithography methods.

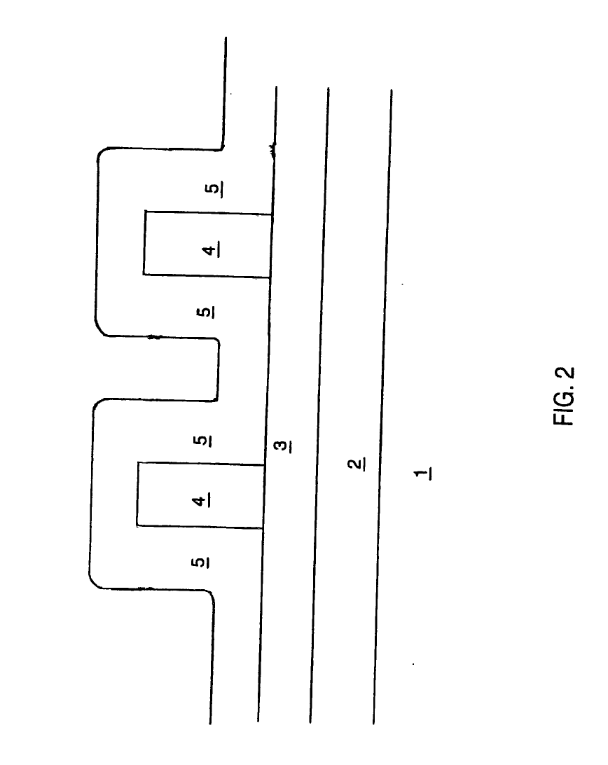

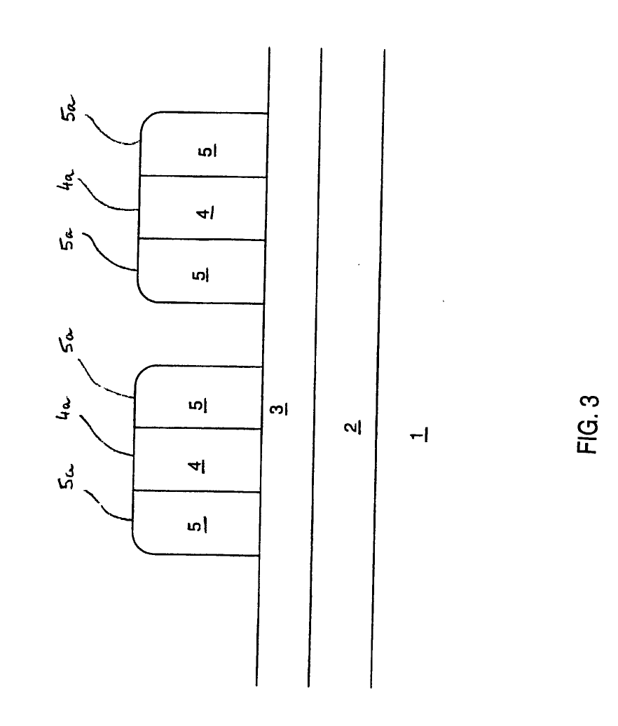

FIGS. 2 and 3 show how, after removing the photoresist, a layer 5 is deposited isotropically on the entire substrate 1 and is then etched anisotropically, with the result that a respective spacer 5a is produced at the edge of the structures 4a. The thickness of this spacer 5a corresponds to the width of the structures that will be fabricated. The deposited layer 5 is completely removed from the surface of the structures 4a during the anisotropic etching in the vertical direction. In this case, the layer 5 is etched selectively with respect to the first masking layer 3. In this case, the structures 4a are permitted to be attacked, but the first masking layer 3 is attacked as little as possible. Therefore, the first masking layer 3 is made of a material that is more resistant to etching than the material of the second masking layer 4. The layer 5 is thus etched selectively with respect to the first masking layer 3. The layer 5 is typically composed of oxide or nitride.

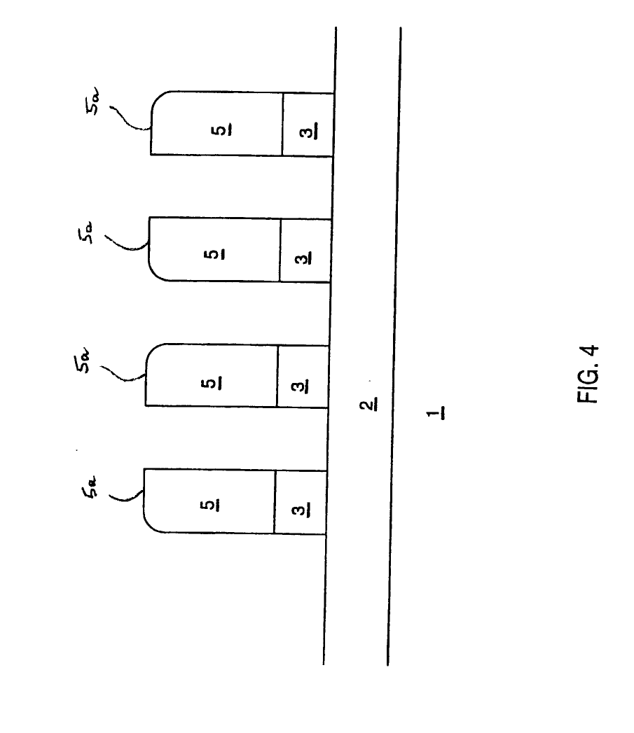

FIG. 4 shows a cross sectional view through the semiconductor device to be fabricated after the second masking layer 4 has been completely removed, and while the spacers 5a remain. The second masking layer 4 is removed by selective wet etching. The remaining spacers 5a now serve as a mask for patterning the layer 3, and if appropriate, also for patterning the layer 2. If necessary from the aspect ratio, the layer 5 may alternatively, also be removed wet-chemically prior to patterning the layer 2.

Equally, the structures 4a can be protected by a block mask (generally a photoresist) during this step, resulting in wider masks for patterning the masking layer 3. The minimum width of the structures fabricated in this way in the layer 3 is three times the minimum width of the structures that will subsequently be fabricated in the layer 2 (i.e. the width of a structure 4a plus the width of the two adjoining spacers 5a).

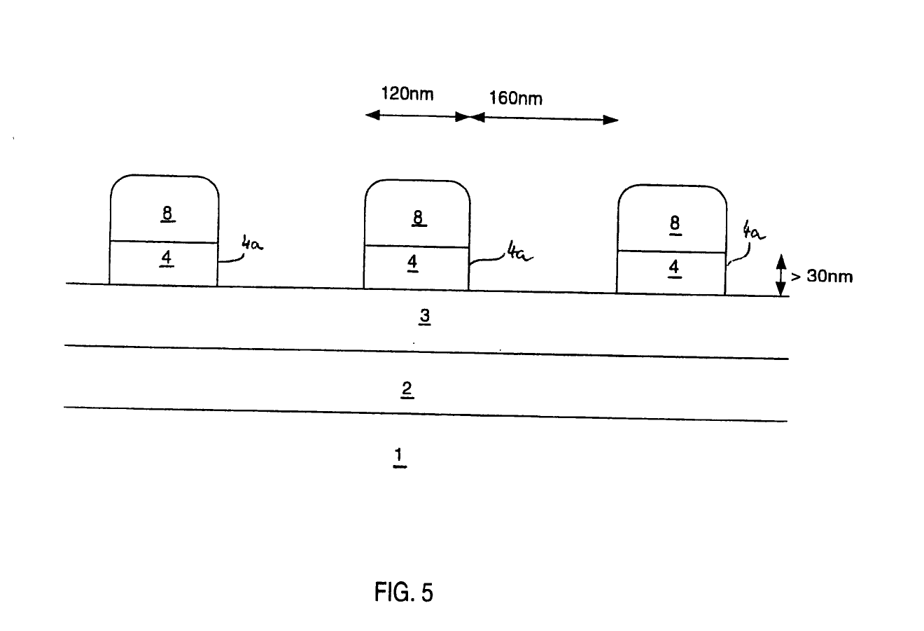

FIGS. 5 to 8 illustrate the fabrication of a semiconductor device according to a second exemplary embodiment of the invention (“double spacer method”). Once again a layer 2 that will be patterned and a first masking layer 3 are applied to a substrate 1. Typically, the substrate 1 is composed of silicon, layer 2 is composed of a material or a material sequence suitable for fabricating interconnects (polysilicon or metal), and the first masking layer 3 is composed of oxide or nitride. A second masking layer 4 is applied to the first masking layer 3 and is essentially resistant to the dry etching of the material of the first masking layer 3. Alternatively the second masking layer 4 can nevertheless also be dry-etched selectively with respect to the material of the second masking layer 4. The second masking layer 4 is typically composed of polysilicon.

The second masking layer 4 only has to be about one third as thick as the width of the structures that will later be fabricated in the layer 2, in order to ensure sufficient profiling of the spacers that will be added in a later fabrication step. This reduction of the required material thickness of the second masking layer 4 is an advantage over the single spacer method.

The second masking layer 4 is patterned selectively with respect to the first masking layer 3 by using a photoresist layer 8 and dry etching. In the case of the double spacer method, the periodicity of the mask structures is about twice as large as the periodicity of the structures that will be fabricated in the layer 2. The line and gap, i.e. the structures 4a formed in the second masking layer 4 and the interspaces lying in between, are virtually in the ratio 1:1, with each line being somewhat narrower than half of the periodicity. In this case, larger periodicity and larger structure widths considerably simplify the lithography process, also in comparison with the single spacer method.

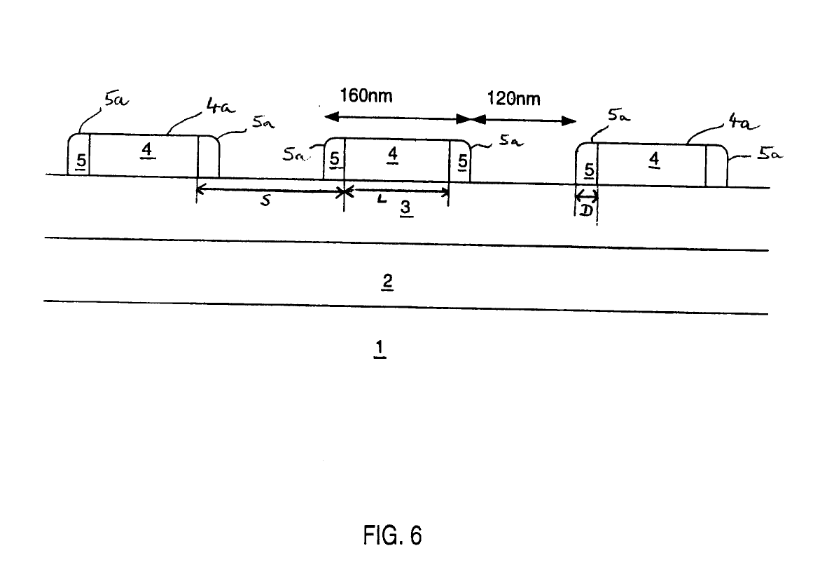

FIG. 6 illustrates how, after removing the photoresist 8, a layer 5 is deposited isotropically on the surface of the semiconductor device that will be fabricated and is then etched anisotropically, with the result that respective first spacers 5a are formed at the edge of the structures 4a. These spacers 5a each have a width that amounts to approximately one third of the width of the structures that will be fabricated in the layer 2. The spacers 5a formed from the layer 5 can be deposited and removed anisotropically from the surface of the structures 4a and the first masking layer 3 significantly better than the comparatively thicker first spacers 5a of the single spacer method.

FIGS. 5 and 6 reveal the line/gap ratio of the lithography more precisely. Let L be the line width of a structure 4a, S the gap width between two structures 4a without the grown first spacers 5a, and D the spacer width, then L+D=S−D. It again holds true that the layer 5 is etched selectively with respect to the first masking layer 3 and is preferably more resistant to etching than the second masking layer 4. The layer 5 is typically composed of oxide or nitride.

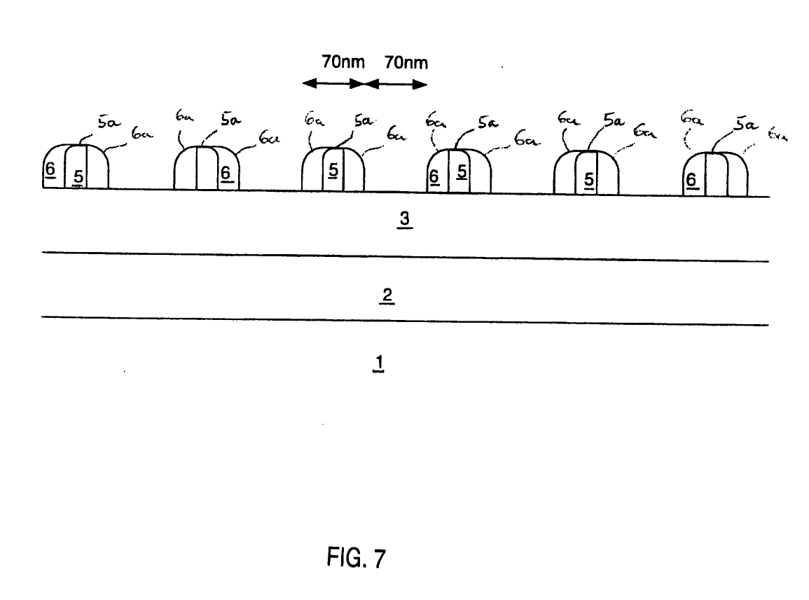

FIG. 7 shows that in a further fabrication step, after forming the spacers 5a, the material of the second masking layer 4 is completely removed, with the result that only the first spacers 5a remain. This is generally effected by selective wet etching. After the removal of the second masking layer 4, a further layer 6 is deposited isotropically and is etched anisotropically, with the result that second spacers 6a grow around the first spacers 5a. In this case, the width of each second spacer 6a again amounts to about one third of the later structure width, with the result that the respective width of the first spacers 5a with the second spacers 6a grown on the right and on the left corresponds to the width of the structure that will subsequently be formed in the layer 2. When the prescribed thicknesses are complied with precisely, the result is a line/gap ratio of 1:1 with a periodicity of half the original lithographic period.

The layers 5 and 6 are typically composed of the same material.

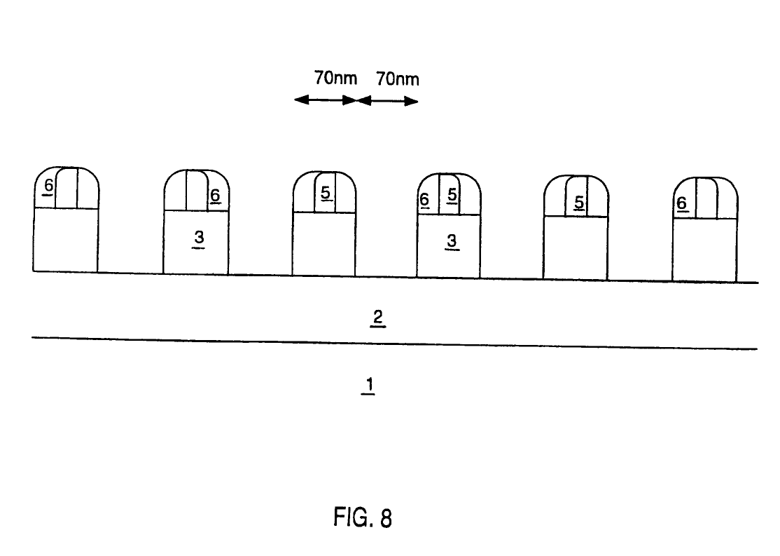

FIG. 8 shows how the structures formed from the layers 5 and 6 serve as a mask for patterning the layer 3, and if necessary, also for patterning the layer 2. If necessary from the aspect ratio, the layer 5 can also be removed wet-chemically, for example, prior to patterning the layer 2.

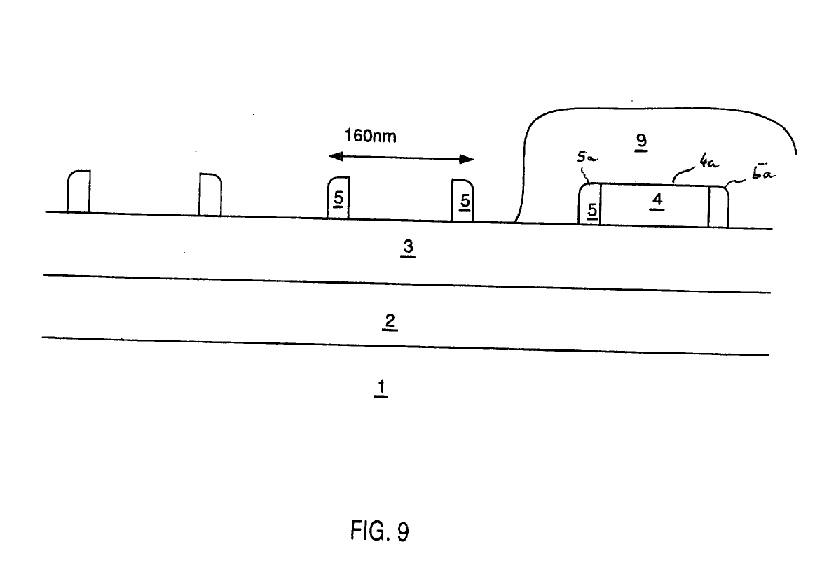

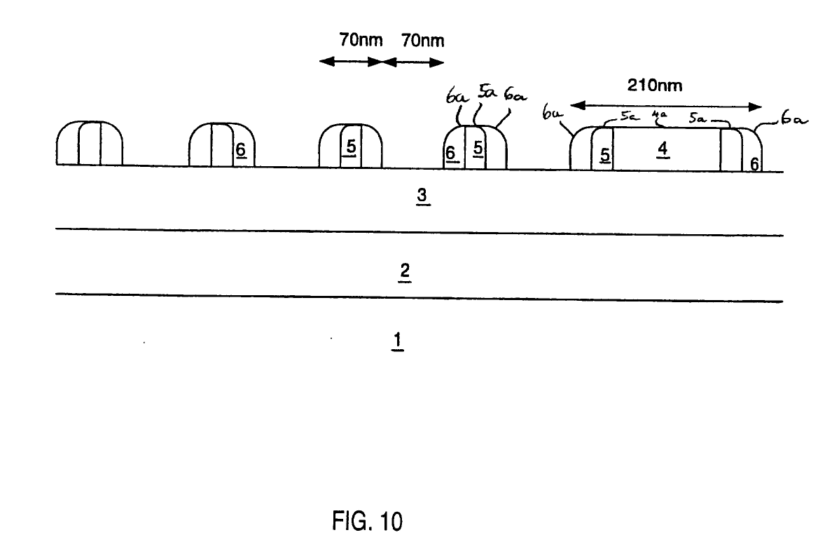

FIGS. 9 and 10 show how wider structures can also be fabricated by using the double spacer method. The wider structure 4a is protected, after forming the spacers 5a, by a photoresist mask 9 patterned in a very large-area manner, with the result that, during the step of removing the layer 4 (this step has been described with reference to FIG. 7), the layer 4 is not attacked below the photoresist 9, and therefore, still exists as a mask during the later patterning of the layer 3. In the example shown, the mask—remaining in FIG. 10—including the structure 4a surrounded by the spacers 5a and 6a is three times as wide as the structure formed only from the spacers 5a and 6a.

Since, however, in contrast to the single spacer method, the width of the structure 4a in FIG. 10 does not correspond to that of the finer structures (since such finer structures can be formed from the spacers 5a and 6a in the double spacer method), the resolution capability in the double spacer method is limited by the lithographic step for fabricating the structures 4a to an even lesser extent than in the single spacer method.

Typically, a structure 4a can be produced lithographically whose width corresponds approximately to 1.7 times the width of the finer structures (from 2L−D, where D=L/3), with the result that the total structure including the structure 4a with the spacers 5a and 6a is about three times as wide as a finer structure including the spacers 5a and 6a.

It should be noted that the invention is not restricted to the exemplary embodiments described, but rather encompasses modifications in the context of the scope of protection defined by the claims. In particular, it should be observed that the dimensions specified in the figures are provided merely by way of example.

I claim:

1. A method for producing a mask for fabricating a semiconductor device, which comprises:
applying a masking layer to a substrate;
selectively removing regions of the masking layer for forming masking structures;
applying a first layer to the masking structures and also in interspaces between the masking structures;
selectively removing regions of the first layer for forming first spacers between the masking structures; and
removing the masking structures for forming the mask from the first spacers for subsequently producing structures of the semiconductor device.

2. The method according to claim 1, wherein: the mask forms a hard mask.

3. The method according to claim 1, wherein: the step of selectively removing the regions of the masking layer is carried out by performing a selective etching.

4. The method according to claim 3, wherein: the selective etching is a dry etching.

5. The method according to claim 1, wherein: the step of selectively removing the regions of the first layer is carried out by performing a selective etching.

6. The method according to claim 5, wherein: the selective etching of the first layer is an anisotropic etching.

7. The method according to claim 1, wherein: the step of applying the first layer to the masking structures is carried out by performing an isotropic deposition.

8. The method according to claim 1, wherein: the step of removing the masking structures is carried out by performing a selective wet etching.

9. The method according to claim 1, wherein: the first layer is made of oxide.

10. The method according to claim 1, wherein: the first layer is made of nitride.

11. The method according to claim 1, wherein: the masking layer includes a first masking layer and a second masking layer applied to the first masking layer.

12. The method according to claim 11, wherein: the second masking layer is more resistant to a dry etching than the first masking layer.

13. The method according to claim 11, wherein: the second masking layer can be etched selectively with respect to the first masking layer.

14. The method according to claim 11, wherein: the second masking layer is made of polysilicon.

15. The method according to claim 11, wherein: the first masking layer is made of oxide.

16. The method according to claim 11, wherein: the first masking layer is made of nitride.

17. The method according to claim 1, wherein: each one of the masking structures has a width equal to about a third of a distance between two of the masking structures.

18. The method according to claim 1, wherein: each one of the first spacers has a width that is essentially equal to a distance between two of the first spacers.

19. The method according to claim 18, wherein: each one of the masking structures has a width that is essentially equal to the width of each one of the first spacers.

20. The method according to claim 1, comprising:
applying a second layer to the first spacers and also into interspaces lying between the first spacers; and
selectively removing regions of the second layer for forming second spacers between the first spacers.

21. The method according to claim 20, wherein: the step of selectively removing the regions of the second layer is carried out by performing a selective etching.

22. The method according to claim 21, wherein: the selective etching that is performed to selectively remove the regions of the second layer is an anisotropic etching.

23. The method according to claim 20, wherein: the step of applying the second layer is carried out by performing an isotropic deposition.

24. The method according to claim 20, wherein: the second layer is made of oxide.

25. The method according to claim 20, wherein: the second layer is made of nitride.

26. The method according to claim 20, wherein: each one of the first spacers has a width equaling approximately one third of a width of each one of the masking structures.

27. The method according to claim 20, wherein:
L+D=S−D, where L is a width of each one of the masking structures, S is a distance between two of the masking structures, and D is a width of each one of the first spacers.

28. The method according to claim 20, wherein: the width of each one of the first spacers is approximately equal to a width of each one of the second spacers.

29. A method for fabricating a semiconductor device, which comprises:
providing a substrate;
applying a layer, which will be patterned, to the substrate;
applying a mask to the layer that will be patterned by:
applying a masking layer to the substrate,
selectively removing regions of the masking layer for forming masking structures,
applying a first layer to the masking structures and also in interspaces between the masking structures,
selectively removing regions of the first layer for forming first spacers between the masking structures, and
removing the masking structures for forming the mask from the first spacers for subsequently producing structures of the semiconductor device; and
using the mask to pattern the layer.

30. The method according to claim 29, which comprises:
applying a second layer to the first spacers and also into interspaces lying between the first spacers;
selectively removing regions of the second layer for forming second spacers between the first spacers;
applying a protective layer above at least one of the masking structures after forming the first spacers;
removing ones of the masking structures that are not provided with the protective layer; and
removing the protective layer.

31. The method according to claim 30, wherein: the protective layer is formed by a photoresist mask.
